(19) United States
(12) Patent Application Publication
(10) Pub. No.: US 2012/0147577 A1
(43) Pub. Date: Jun. 14, 2012

(54) MOUNTING STRUCTURE FOR ANTENNA OF ELECTRONIC DEVICE

(75) Inventors: XIAO-HUI ZHOU, Shenzhen City (CN); TING-TING ZHAO, Shenzhen City (CN); HONG LI, Shenzhen City (CN); MIN-LI LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/070,535

(22) Filed: Mar. 24, 2011

(30) Foreign Application Priority Data
Dec. 13, 2010 (CN) 201010584965.1

(51) Int. Cl. H05K 7/00; H01Q 1/12

(52) U.S. Cl. 361/760; 248/224.8

(57) ABSTRACT

A mounting structure for an antenna of an electronic device includes a casing and a tube assembly. The tube assembly encloses the antenna of the electronic device. The mounting structure includes a securing member mounted on the casing and a protruding portion protruding out from the casing. A receiving hole is defined in the protruding portion. The securing member includes a securing portion, and the securing portion is with an opening therein. The securing portion is aligned with and spaced from the protruding portion. Opposite ends of the tube assembly are inserted into the through hole of the protruding portion and the opening of the securing portion, respectively.

### BACKGROUND

1. Technical Field

The present disclosure relates to mounting structures and, more particularly, to a mounting structure for an antenna of an electronic device.

2. Description of Related Art

An antenna of an electronic device is configured for receiving and sending data wirelessly to and from base stations. Usually, a locking portion is provided for fixing the antenna on the electronic device. However, the locking portion is easily deformed and loosened because of frequent used, thus, it is hard to fix the antenna to the electronic device firmly.

Therefore, what is needed is a mounting structure for antenna of electronic device, which can overcome the above described shortcomings.

### BRIEF DESCRIPTION OF THE DRAWINGS

FIG. 1 is an assembled, isometric view of a mounting structure for an antenna of an electronic device in accordance with an exemplary embodiment of the present disclosure, showing the antenna mounted to the mounting structure.

FIG. 2 is a partly disassembled view of FIG. 1.

FIG. 3 is a disassembled view of a tube assembly and the antenna of FIG. 2.

FIG. 4 is a partially enlarged view of the mounting structure and the antenna of FIG. 1.

FIG. 5 is similar to FIG. 4, but in different view.

### DETAILED DESCRIPTION

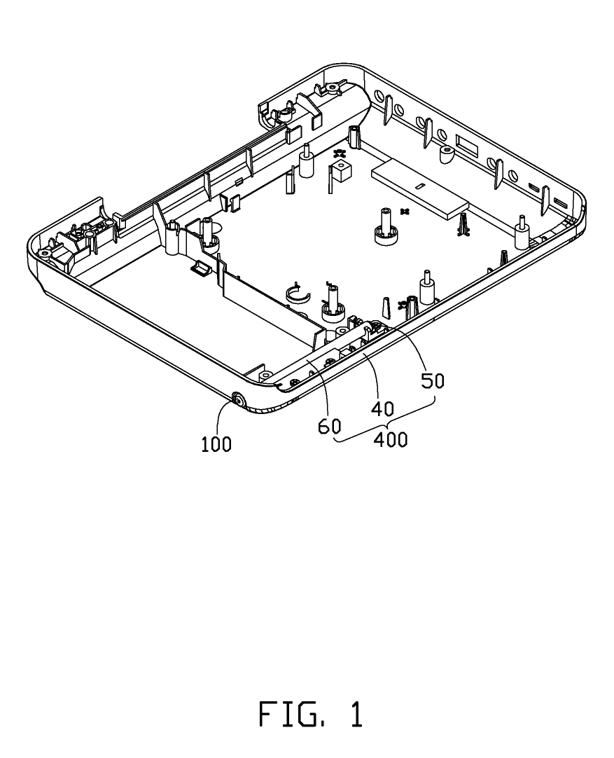

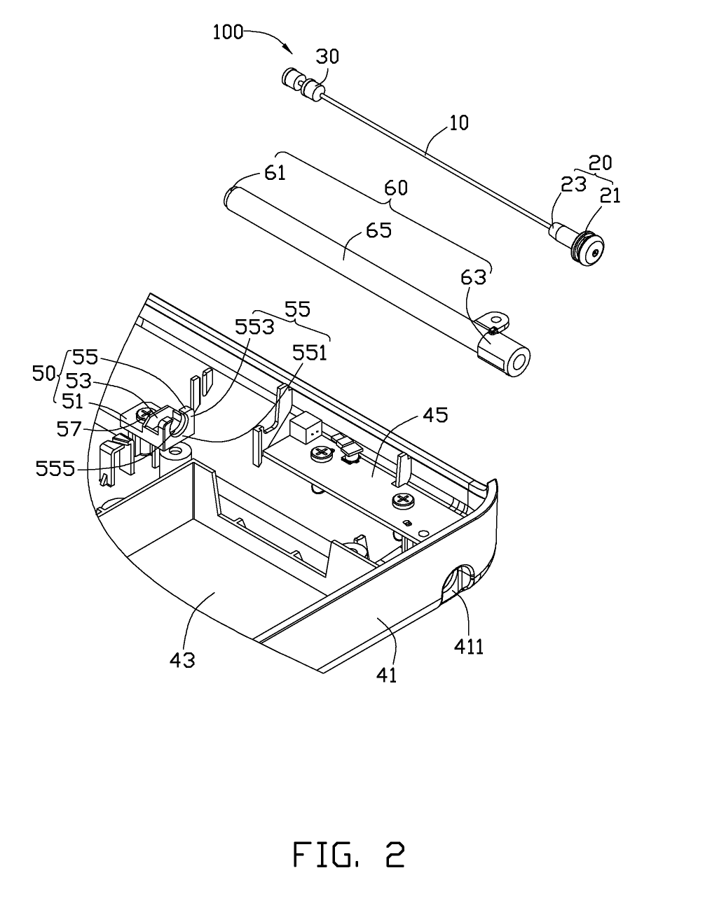

Referring to FIGS. 1 to 2, an exemplary embodiment of an antenna 100 of an electronic device and a mounting structure 400 for mounting the antenna 100 is shown. The mounting structure 400 includes a casing 40, a securing member 50 mounted on the casing 40, and a tube assembly 60. Opposite ends of the tube assembly 60 are inserted into the casing 40 and the securing member 50, respectively. The tube assembly 60 encloses the antenna 100 therein.

The antenna 100 includes an elongated cylindrical main body 10, an operating member 20 secured on one end of the main body 10 and a stopper member 30 secured on the other end of the main body 10. The operating member 20 includes a cylindrical handle 21 and a cylindrical fixing post 23 extending from the handle 21 and protruding outward along an axis of the handle 21. The fixing post 23 is arranged between the handle 21 and the stopper member 30. The main body 10 is made of electrically conductive metal, such as copper or aluminum. A diameter of the handle 21 is larger than that of the fixing post 23. One end of the main body 10 is inserted through the center of the fixing post 23 and resists the handle 21; therefore the operating member 20 is securely connected to the main body 10, and the operating member 20 can be rotated out and detached from the main body 10. The main body 10 includes two spaced cylindrical bodies, which enclose the main body 10, and are opposite to the operating member 20. A diameter of the fixing post 23 of the operating member 20 and a diameter of the stopper member 30 both are larger than that of the main body 10, respectively.

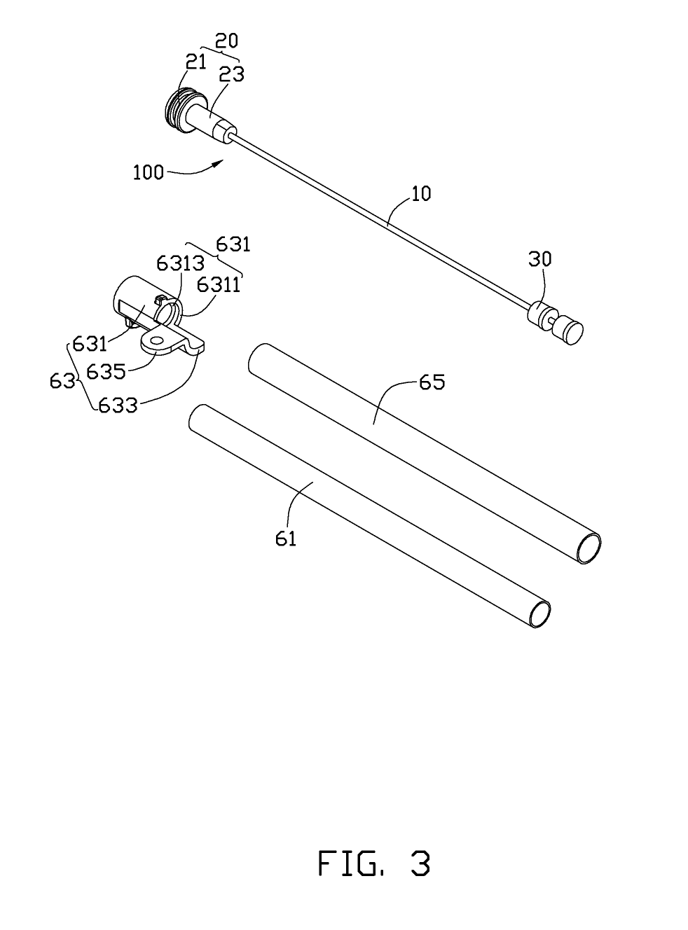

Referring to FIG. 3, the tube assembly 60 includes a hollow cylindrical electrically conductive body 61, a fixture 63 enclosing one end of the electrically conductive body 61, and a channel 65 enclosing the other end of the electrically conductive body 61 resisting the fixture 63. The channel 65 is made of insulated material. The fixture 63 includes a hollow sleeve portion 631, an arcuate extending portion 633 extending outward from an end of the sleeve portion 631 along an axis of the sleeve portion 631, and a fastener 635 protruding outward from a peripheral edge of the extending portion 633.

The sleeve portion 631 is a hollow cylinder and defines a stepped structure;

therefore, the sleeve portion 631 defines a first sleeve portion 6311 with a larger inner diameter and a second sleeve portion 6313 with a smaller inner diameter extending from the first sleeve portion 6311 and away from the fastener 635. One end of the conductive body 61 extends through the first sleeve portion 6311 and abuts against the second sleeve portion 6313. One end of the channel 65 is received in the first sleeve portion 6311 and abuts against the second sleeve portion 6313. The extending portion 633 of the fixture 63 extends from the first sleeve portion 6311 and contacts an outer surface of the channel 65. In the present embodiment, the fixture 63 is made of metal. The fastener 635 is substantially square-shaped for fixing the fixture 63 on the casing 40 and electrically connecting to a printed circuit board (PCB) 45 of the electronic device. The conductive body 61 is electrically connected with the fixture 63. An inner diameter of the conductive body 61 is larger than the largest diameters of the main body 10 and the stopper member 30 of the antenna 100; therefore, the main body 10 and the stopper member 30 can be received in the conductive body 61. An inner diameter of the second sleeve portion 6313 of the fixture 63 is smaller than the largest diameters of the stopper member 30 of the antenna 100 and the handle 21, but larger than the largest diameter of the fixing post 23.

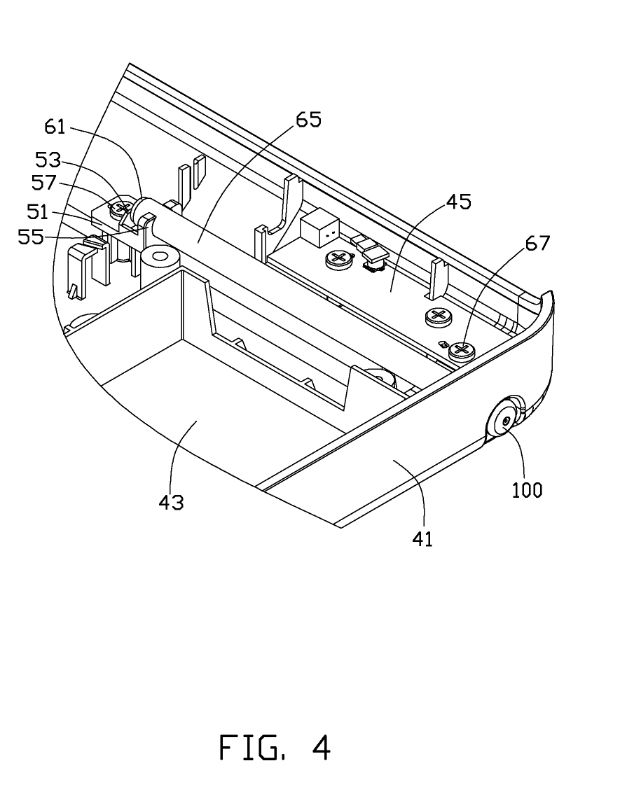

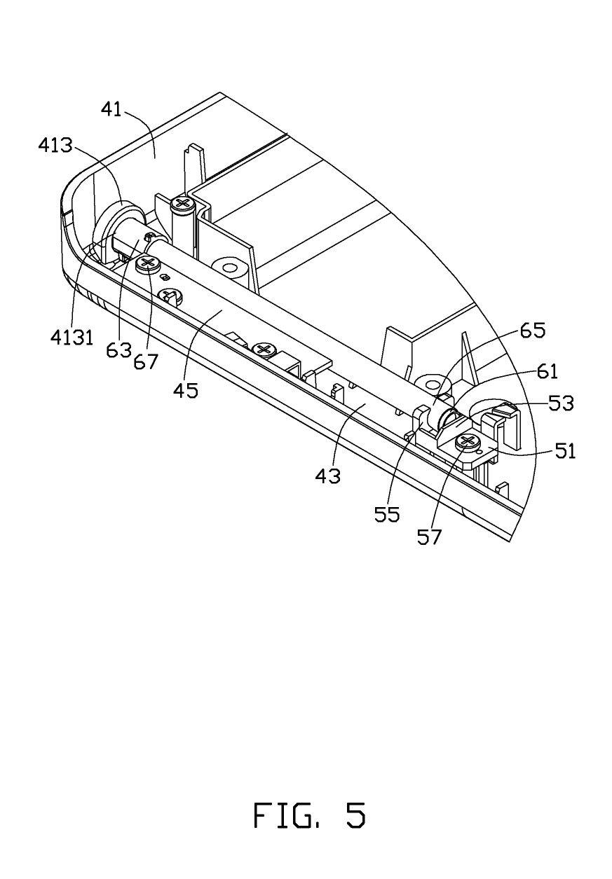

Referring to FIGS. 4 and 5, the casing 40 includes a base 43 and a side wall 41 extending upward from a peripheral edge of the base 43. The side wall 41 defines a circular through hole 411 therein for receiving the operating member 20 of the antenna 100. A protruding portion 413 is projected from an inner surface of the side wall 41. The protruding portion 413 defines a receiving hole 4131, which communicates and is aligned with the through hole 411. An inner diameter of the receiving hole 4131 is smaller than that of the through hole 411, but is larger than the largest diameter of the fixture 63 of the tube assembly 60. The second sleeve portion 6313 of the fixture 63 is received in the receiving hole 4131 of the protruding portion 413 and resists the casing 40.

The securing member 50 is mounted on the base 43 of the casing 40. The securing member 50 includes an elongated connecting board 51, a baffle board 53 extending from a center of an upper surface of the connecting board 51 and extending upward breadthwise of the connecting board 51. In addition, a securing portion 55 extends upward from one end of the connecting board 51 and extends breadthwise of the connecting board 51. The securing portion 55 is aligned with and is spaced from the protruding portion 413, and is arranged between the connecting board 51 and the protruding portion 413.

A pivot 57 extends through the connecting board 51 and engages with the base 43; thus, the securing member 50 is secured on the base 43. The baffle board 53 is configured for limiting one end of the tube assembly 60. The securing portion 55 and the baffle board 53 are substantially parallel to and spaced from each other. The securing portion 55 includes a rectangle bracket 551 extending perpendicularly from the connecting board 51, and two arms 553 extending from two lateral sides of the bracket 551. The two arms 553 are spaced from each other. The two arms 553 and the bracket 551 cooperatively define a U-shaped opening 555. The opening 555 is used for clasping the tube assembly 60. The opening 555 is aligned with the receiving hole 4131 of the side wall 41, and a diameter of the opening 555 is slightly smaller than that of the receiving hole 4131.

In assembly of the antenna 100 with the mounting structure 400, the securing member 50 is fixed on the base 43 of the casing 40 to make the opening 555 align with the receiving hole 4131 of the protruding portion 413. The fixture 63 encloses the conductive body 61 of the tube assembly 60. The second sleeve portion 6313 is received in the receiving hole 4131 of the protruding portion 413 and resists the side wall 41 of the casing 40. The operating member 20 rotates out and detaches from the main body 10, and the main body 10 and the stopper member 30 of the antenna 100 are inserted through the conductive body 61 of the tube assembly 60 from one end of the tube assembly 60 away from the side wall 41. Moreover, the end of the tube assembly 60 is inserted into the opening 555 of the securing member 50 and resists the baffle board 53. The fastener 635 is arranged at a bottom of the PCB 45, and a pivot 67 extends through the PCB 45 and the fastener 635 of the fixture 63; therefore, the fixture 63 is secured on the casing 40, and the fastener 635 is electrically connected to the PCB 45. The fixing post 23 of the operating member 20 of the antenna 100 extends through the through hole 411 of the side wall 41 and the protruding portion 413, and then encloses an end of the main body 10 which is away from the stopper member 30; therefore, the fixing post 23 of the operating member 20 is secured on the main body 10 and is received in the fixture 63, and the handle 21 protrudes outward from the through hole 411. Because the largest diameter of the stopper member 30 is larger than the inner diameter of the second sleeve portion 6313 of the fixture 63, the stopper member 30 can be abutting against the second sleeve portion 6313, thus the antenna 100 can be slid relative to the assembly tube 60, but cannot come out of the tube 60; therefore, the antenna 100 is secured on the mounting structure 400.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A mounting structure for an antenna of an electronic device, comprising:
a casing;
a tube assembly enclosing the antenna;
a securing member mounted on the casing, the securing member comprising a securing portion, the securing portion having an opening defined therein; and
a protruding portion protruding out from the casing, a receiving hole being defined in the protruding portion, the securing portion being aligned with and spaced from the protruding portion;
wherein opposite ends of the tube assembly are inserted into the receiving hole of the protruding portion and the opening of the securing portion, respectively.

2. The mounting structure of claim 1, wherein the securing portion comprises a bracket and two arms extending from two lateral sides of the bracket, and the arms and the bracket cooperatively defining the opening of the securing portion.

3. The mounting structure of claim 2, wherein the securing member further comprises a baffle board spaced from the securing portion for resisting the tube assembly.

4. The mounting structure of claim 3, wherein the securing member further comprises a connecting board connected to the securing portion and the baffle board, and the securing member being secured on a base of the casing by the connecting board.

5. The mounting structure of claim 1, wherein the tube assembly comprises a hollow conductive body, a fixture enclosing one end of the conductive body, and a channel enclosing the other end of the conductive body, the channel of the tube assembly being received in the opening of the securing portion of the securing member, and the fixture of the tube assembly being received in the receiving hole of the protruding portion.

6. The mounting structure of claim 5, wherein the fixture is hollow cylindrical-shaped, and comprises a first sleeve portion and a second sleeve portion, the second sleeve portion having an inner diameter less than that of the first sleeve portion, the second sleeve portion extending from the first sleeve portion, one end of the conductive body extending through the first sleeve portion and abutting against the second sleeve portion, one end of the channel being received in the first sleeve portion and resisting the second sleeve portion, and the second sleeve portion being received in the receiving hole of the protruding portion and resisting the casing.

7. The mounting structure of claim 5, wherein a fastener protrudes outwardly from a peripheral of the fixture, a printed circuit board being secured on the casing, and the fastener being mounted to the printed circuit board.

8. The mounting structure of claim 7, wherein the fixture is made of metal and electrically connected to the conductive body, and the fastener is electrically connected to the printed circuit board.

9. The mounting structure of claim 7, wherein the channel is made of insulated material.

10. The mounting structure of claim 6, wherein the casing defines a through hole aligned and communicating with the receiving hole of the protruding portion, the antenna comprising a main body, an operating member secured on one end of the main body and a stopper member secured on the other end of the main body, the main body and the stopper member of the antenna being received in the conductive body, the stopper member of the antenna resisting the second sleeve portion, the operating member of the antenna being received in the through hole of the casing and extending through the receiving hole of the protruding portion for connecting to the main body.
